(19) United States
(12) Patent Application Publication
(10) Pub. No.: US 2019/0386241 A1
(43) Pub. Date: Dec. 19, 2019

(54) ORGANIC LIGHT-EMITTING DIODE DISPLAY AND METHOD FOR FABRICATING THE SAME

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wei YU, Wuhan, Hubei (CN)

(21) Appl. No.: 15/735,932

(22) PCT Filed: Nov. 23, 2017
(86) PCT No.: PCT/CN2017/112506

§ 371 Date: Dec. 12, 2017

(30) Foreign Application Priority Data
Oct. 11, 2017 (CN) 201710962798.1

(51) Int. Cl. H01L 51/52; H01L 27/32; H01L 51/56

(52) U.S. Cl. CPC H01L 51/5234; H01L 51/5228; H01L 2227/323; H01L 51/525; H01L 51/56; H01L 27/3244

(57) ABSTRACT

The present invention discloses an organic light-emitting diode (OLED) display and a method for fabricating the same. The method includes: sequentially forming an anode, an organic lighting layer, and a cathode on a first substrate; coating at an edge of a package cover with a sealant and coating a region enclosed by the sealant and the package cover with a transparent conductive glue; and laminating the package cover to the first substrate through the sealant to form a closed space, and solidifying the transparent conductive glue and the cathode and bonding the transparent conductive glue to the cathode. Accordingly, the present invention reduces the resistance of electrodes, thereby increasing the resistivity of the cathode, improving the package effect, and reducing heat and power consumption.

### RELATED APPLICATIONS

The present application is a National Phase of International Application Number PCT/CN2017/112506, filed Nov. 23, 2017, and claims the priority of China Application No. 201710962798.1, filed Oct. 11, 2017.

### FIELD OF THE DISCLOSURE

The present invention relates to a display technical field, particularly to an organic light-emitting diode display and a method for fabricating the same.

### BACKGROUND

An organic light-emitting diode (OLED) display, also called an organic electroluminescent display, is a novel display panel. It features simple technique, low cost, low power consumption, high brightness, wide working temperature, low thickness, and short response time. Besides, the OLED display is easily applied to a color and large-screen display. Thus, the OLED display has a broad application prospect.

The existing OLED displays include top-emitting displays and bottom-emitting display. Take a top-emitting display as example. In an OLED display, an organic lighting layer is added between an anode and a cathode or between conductive layers. When applying a voltage to the anode and the cathode, the organic lighting layer will emit light from the translucent cathode to the substrate.

In order to ensure that the light is emitted from the translucent cathode to the substrate, the cathode has a very thin thickness of several nanometers. As a result, the translucent cathode has very high resistance. When the anode and the cathode commonly drive the organic lighting layer, more energy will be consumed to generate more heat, so that the working state of the array substrate is easily affected.

### SUMMARY

In order to overcome the abovementioned problem, the primary objective of the present invention is to provide an organic light-emitting diode (OLED) display and a method for fabricating the same, which reduces the resistance of electrodes, thereby increasing the resistivity of the cathode; improving the package effect; and reducing heat and power consumption.

To achieve the abovementioned objectives; the present invention proposes a method for fabricating an organic light-emitting diode display comprising: sequentially forming an anode, an organic lighting layer; and a cathode on a first substrate; coating at an edge of a package cover with a sealant and coating a region enclosed by the sealant and the package cover with a transparent conductive glue; laminating the package cover to the first substrate through the sealant to form a closed space; using ultraviolet rays to irradiate the sealant to solidify the sealant; and heating the transparent conductive glue to solidify the transparent conductive glue, thereby solidifying the transparent conductive glue and the cathode and bonding the transparent conductive glue to the cathode.

The present invention also proposes a method for fabricating an organic light-emitting diode display comprising: sequentially forming an anode; an organic lighting layer, and a cathode on a first substrate; coating at an edge of a package cover with a sealant and coating a region enclosed by the sealant and the package cover with a transparent conductive glue; and laminating the package cover to the first substrate through the sealant to form a closed space, and solidifying the transparent conductive glue and the cathode and bonding the transparent conductive glue to the cathode.

The present invention further proposes an organic light-emitting diode display comprising; a first substrate sequentially provided with an anode, an organic lighting layer, and a cathode thereon; and a package cover laminated to the first substrate through a sealant coated at an edge of the package cover, wherein a region enclosed by the sealant and the package cover is coated with a transparent conductive glue, and the transparent conductive glue and the cathode are solidified, and the transparent conductive glue is bonded to the cathode.

Distinct from the conventional technology, the present invention coats an edge of a package cover with a sealant and coating a region enclosed by the sealant and the package cover with the transparent conductive glue, laminates the package cover to the first substrate through the sealant to form a closed space, reduces the resistance of electrodes to increase the resistivity of the cathode, improve the package effect, and reduce heat and power consumption, and prevents water and oxygen from entering into the OLED display through the sealant to age the organic lighting layer and affect the life of the OLED display.

### BRIEF DESCRIPTION OF THE DRAWINGS

FIG. 1 is a flowchart of fabricating an organic light-emitting diode display according to one embodiment of the present invention;

FIG. 2 is a cross-sectional view of forming a first substrate, an anode, an organic lighting layer, and a cathode of the organic light-emitting diode display using the flowchart of FIG. 1 according to one embodiment of the present invention;

FIG. 3 is a cross-sectional view of forming a package cover, a sealant, and a conductive glue of the organic light-emitting diode display using the flowchart of FIG. 1 according to one embodiment of the present invention;

FIG. 4 is a cross-sectional view of an organic light-emitting diode display according to one embodiment of the present invention; and

FIG. 5 is a cross-sectional view of an organic light-emitting diode display according to another embodiment of the present invention.

### DETAILED DESCRIPTION OF PREFERRED EMBODIMENTS

The embodiments described in the embodiments of the present application will be apparent from the following description of embodiments of the present application, and it will be apparent that the described embodiments are part of the embodiments of the present application and not all of the embodiments. Based on the embodiments of the present application, all other embodiments to those of ordinary skill in the art without any creative effort shall fall within the scope of the present application.

Refer to FIG. 1. FIG. 1 is a flowchart of fabricating an organic light-emitting diode display according to one embodiment of the present invention. According to an embodiment of the present invention, method for fabricating an organic light-emitting diode (OLED) display comprises:

Step 100: sequentially forming an anode, an organic lighting layer, and a cathode on a first substrate. In an embodiment, a first substrate is prepared. Then, an anode is formed on the first substrate, and a hole injection layer is formed on the anode, and a hole transporting layer is formed on the hole injection layer, and an organic lighting layer is formed on the hole transporting layer, and an electron transporting layer is formed on the organic lighting layer, and an electron injection layer is formed on the electron transporting layer, and a cathode is formed on the electron injection layer. Specifically, the anode, the hole injection layer, the hole transporting layer, the organic lighting layer, the electron transporting layer, the electron injection layer, and the cathode are sequentially formed on the first substrate, and the organic lighting layer comprises an organic film and organic lighting material.

In an embodiment, the first embodiment is an array substrate that includes a glass substrate, a gate formed on the glass substrate, a gate insulation layer and an oxide film formed on the gate, and a source and a drain formed on the oxide film, wherein the source is separated from the drain by a groove. The first substrate comprises at least one of glass and quartz.

Specifically, the OLED display is a top-emitting OLED display. The anode comprises metal, and the cathode comprises translucent metal.

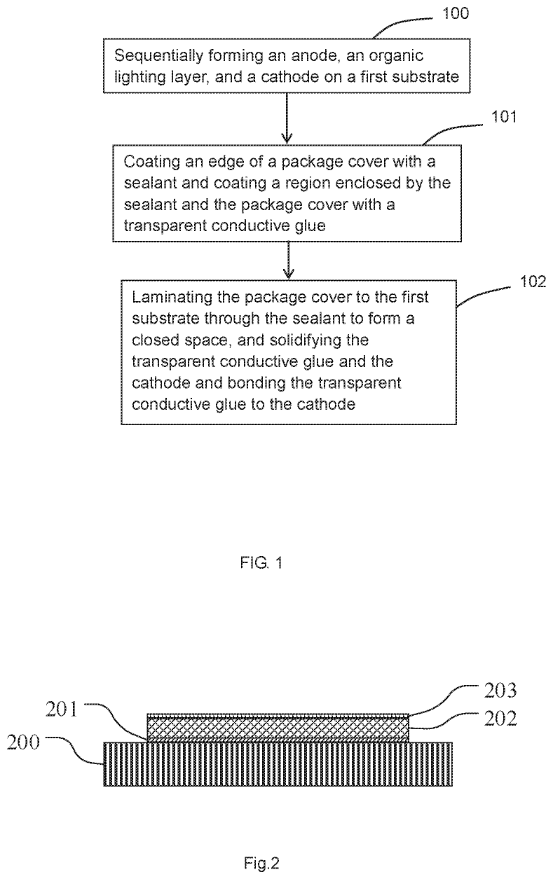

FIG. 2 is a cross-sectional view of forming a first substrate, an anode, an organic lighting layer, and a cathode of the organic light-emitting diode display using the flowchart of FIG. 1 according to one embodiment of the present invention. Specifically, an anode 201 is formed on a first substrate 200, and a hole injection layer (not shown) is formed on the anode, and a hole transporting layer (not shown) is formed on the hole injection layer, and an organic lighting layer 202 is formed on the hole transporting layer, and an electron transporting layer (not shown) is formed on the organic lighting layer 202, and an electron injection layer (not shown) is formed on the electron transporting layer, and a cathode 203 is formed on the electron injection layer.

When a voltage is applied to the anode 201 and the cathode 203, electrons and holes are respectively injected into the electron transporting layer and the hole transporting layer from the cathode and the anode, and then drifted to the organic lighting layer 202, and combined in the organic transporting layer 202 to form excitors, thereby stimulating the organic lighting material to emit light. In the embodiment, the organic lighting layer 202 emits light from the translucent metal cathode 203.

Step 101: coating an edge of a package cover with a sealant and coating a region enclosed by the sealant and the package cover with a transparent conductive glue.

In an embodiment, in order to laminating the package cover to the first substrate to form a closed space, the edge of the package cover is coated with the sealant. In an embodiment, the sealant may be a DAM glue.

In order to prevent water and oxygen from entering into the OLED display through the sealant to age the organic material of the organic lighting layer, the region enclosed by the sealant and the package cover is coated with the transparent conductive glue to improve the life of the OLED display.

In an alternative embodiment, the transparent conductive glue may be a transparent electronic glue that comprises sorbitol. In other embodiments, the transparent conductive glue may be applied to electronic elements, but the present invention is not limited thereto.

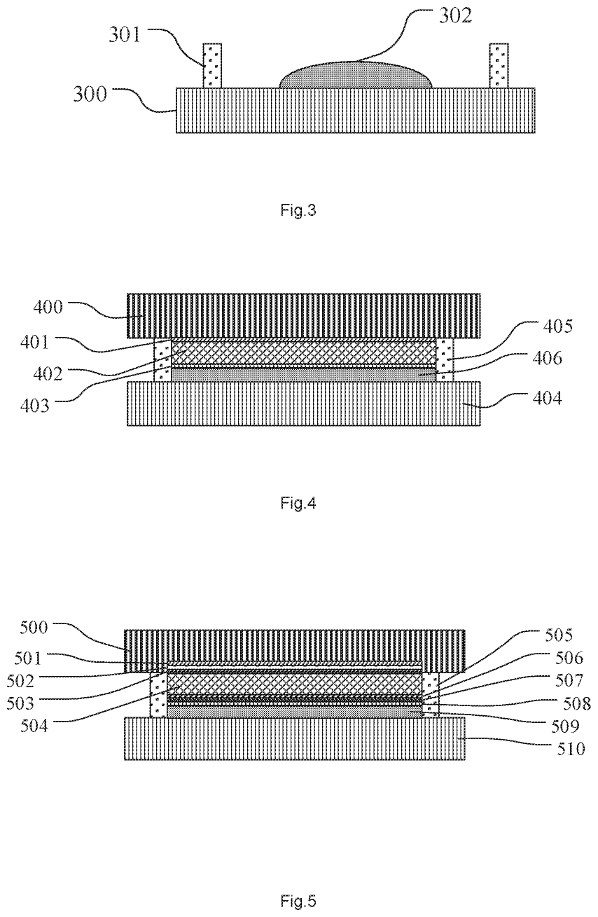

Refer to FIG. 3. FIG. 3 is a cross-sectional view of forming a package cover, a sealant, and a conductive glue of the organic light-emitting diode display using the flowchart of FIG. 1 according to one embodiment of the present invention. The edge of the package cover 300 is coated with the sealant 301. Then, the region enclosed by the sealant 301 and the package cover 300 is coated with the transparent conductive glue 302.

Step 102: laminating the package cover to the first substrate through the sealant to form a closed space, thereby solidifying the transparent conductive glue and the cathode and bonding the transparent conductive glue to the cathode.

In an embodiment, in a vacuum environment, the package cover is laminated to the first substrate through the sealant. The package cover is laminated to the cathode of the first substrate. Wherein, the transparent conductive glue and the cathode are solidified and bonded. During the lamination process, the space between the cathode of the first substrate and the package cover is filled with the transparent conductive glue. The package cover and the first substrate form a closed space.

In order to block water and oxygen, the sealant and the transparent conductive glue are solidified after the package cover is laminated to the first substrate. In the embodiment, ultraviolet rays are used to irradiate the sealant to solidify the sealant, and the transparent conductive glue is heated and solidified.

In other embodiments, the sealant is heated and solidified, and the transparent conductive glue is solidified at a room temperature. A long as the sealant and the transparent conductive glue are solidified, the solidifying way is not limited.

In the present invention, the region enclosed by the package cover and the sealant is coated with the transparent conductive glue, and the package cover is laminated to the first substrate to form a closed space. The present invention reduces the resistance of electrodes to improve the resistivity of the cathode and package effect and reduce power consumption and heat.

Refer to FIG. 4. FIG. 4 is a cross-sectional view of an organic light-emitting diode display according to one embodiment of the present invention. The OLED display comprises a first substrate sequentially provided with an anode 401, an organic lighting layer 402, and a cathode 403 thereon; and a package cover 404 laminated to the first substrate through a sealant 405 coated at an edge of the package cover, wherein a region enclosed by the sealant and the package cover 404 is coated with a transparent conductive glue 406, and the transparent conductive glue 406 and the cathode 403 are solidified, and the transparent conductive glue 406 is bonded to the cathode 403.

The first substrate 400 and the package cover 404 may be at least one of glass and quartz. The OLED display is a top-emitting OLED display. The anode 401 comprises metal and the cathode 403 comprises translucent metal.

Refer to FIG. 5. FIG. 5 is a cross-sectional view of an organic light-emitting diode display according to another embodiment of the present invention. The OLED display has an anode 501, an organic lighting layer 504, and a cathode 508. Besides, the OLED display further comprises a hole injection layer 502, a hole transporting layer 503 between the anode 501 and the organic lighting layer 504. The OLED display further comprises an electron injection layer 506 and an electron injection layer 507 between the organic lighting layer 504 and the cathode 508.

As shown in FIG. 4, when a voltage is applied to the anode 401 and the cathode 403, electrons and holes are respectively injected into the electron transporting layer and the hole transporting layer from the cathode 403 and the anode 401, and then drifted to the organic lighting layer 402, and combined in the organic transporting layer 402 to form excitons, thereby stimulating the organic lighting material to emit light. In the embodiment, the organic lighting layer 402 emits light from the translucent metal cathode 403.

In any of the abovementioned embodiments, the transparent conductive glue may be a transparent electronic glue that comprises sorbitol. In other embodiments, the transparent conductive glue may be applied to electronic elements, but the present invention is not limited thereto. Using the transparent conductive glue 406 or 509 can prevent water and oxygen from entering into the OLED display to age the organic material of the organic lighting layer, thereby improving the life of the OLED display.

In an embodiment, in a vacuum environment, the package cover 404 is laminated to the first substrate 400 through the sealant, so as to form a closed space.

In order to block water and oxygen, the sealant 405 and the transparent conductive glue 406 are solidified after the package cover 404 is laminated to the first substrate 400. In the embodiment, ultraviolet rays are used to irradiate the sealant 405 to solidify the sealant 405, and the transparent conductive glue 406 is heated and solidified.

In other embodiments, the sealant 405 is heated and solidified, and the transparent conductive glue 406 is solidified at a room temperature. A long as the sealant 405 and the transparent conductive glue 406 are solidified, the solidifying way is not limited.

Distinct from the conventional technology, the present invention coats the region enclosed by the package cover and the sealant with the transparent conductive glue, and the package cover is laminated to the first substrate to form a closed space. The present invention reduces the resistance of electrodes to improve the resistivity of the cathode and package effect and reduce power consumption and heat, and prevents water and oxygen from entering into the OLED display through the sealant to age the organic lighting layer and affect the life of the OLED display.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A method for manufacturing an organic light-emitting diode display comprising:
sequentially forming an anode, an organic lighting layer, and a cathode on a first substrate;
coating an edge of a package cover with a sealant, and coating a region enclosed by the sealant and the package cover with a transparent conductive glue;
laminating the package cover to the first substrate through the sealant to form a closed space;
using ultraviolet rays to irradiate the sealant to solidify the sealant; and
heating the transparent conductive glue to solidify the transparent conductive glue, thereby solidifying the transparent conductive glue and the cathode, and bonding the transparent conductive glue to the cathode.

2. The method for manufacturing a organic light-emitting diode display according to claim 1, wherein the step of laminating the package cover to the first substrate through the sealant to form the closed space further comprises a step of laminating the package cover to the first substrate through the sealant to form the closed space in a vacuum environment.

3. The method for manufacturing a organic light-emitting diode display according to claim 1, wherein before the step of sequentially forming the anode, the organic lighting layer, and the cathode on the first substrate, the method further comprises steps of:
forming a gate on a glass substrate;
sequentially forming a gate insulation layer and an oxide layer; and
sequentially forming a source and a drain on the oxide layer, wherein the source is separated from the drain by a groove.

4. The method for manufacturing a organic light-emitting diode display according to claim 1, wherein the transparent conductive glue comprises sorbitol.

5. The method for manufacturing a organic light-emitting diode display according to claim 1, wherein the cathode comprises translucent metal.

6. A method for manufacturing an organic light-emitting diode display comprising:
sequentially forming an anode, an organic lighting layer, and a cathode on a first substrate;
coating an edge of a package cover with a sealant and coating a region enclosed by the sealant and the package cover with a transparent conductive glue; and
laminating the package cover to the first substrate through the sealant to form a closed space, and solidifying the transparent conductive glue and the cathode, and bonding the transparent conductive glue to the cathode.

7. The method for manufacturing a organic light-emitting diode display according to claim 6, wherein the step of laminating the package cover to the first substrate through the sealant to form the closed space further comprises a step of laminating the package cover to the first substrate through the sealant to form the closed space in a vacuum environment.

8. The method for manufacturing a organic light-emitting diode display according to claim 6, wherein after the step of laminating the package cover to the first substrate through the sealant to form the closed space, the method further comprises a step of using ultraviolet rays to irradiate the sealant to solidify the sealant.

9. The method for manufacturing a organic light-emitting diode display according to claim 6, wherein after the step of laminating the package cover to the first substrate through the sealant to form the closed space, the method further comprises a step of heating the transparent conductive glue to solidify the transparent conductive glue, thereby solidifying the transparent conductive glue and the cathode and bonding the transparent conductive glue to the cathode.

10. The method for manufacturing a organic light-emitting diode display according to claim 6, wherein before the step of sequentially forming the anode, the organic lighting layer, and the cathode on the first substrate, the method further comprises steps of:
forming a gate on a glass substrate;
sequentially forming a gate insulation layer and an oxide layer; and
sequentially forming a source and a drain on the oxide layer, wherein the source is separated from the drain by a groove.

11. An organic light-emitting diode display comprising:
a first substrate sequentially provided with an anode, an organic lighting layer, and a cathode thereon; and
a package cover laminated to the first substrate through a sealant coated at an edge of the package cover, wherein a region enclosed by the sealant and the package cover is coated with a transparent conductive glue, and the transparent conductive glue and the cathode are solidified, and the transparent conductive glue is bonded to the cathode.

12. The organic light-emitting diode display according to claim 11, wherein the transparent conductive glue comprises sorbitol.

13. The organic light-emitting diode display according to claim 11, wherein the cathode comprises translucent metal.

14. The organic light-emitting diode display according to claim 11, wherein the sealant is irradiated by ultraviolet rays to be solidified.

15. The organic light-emitting diode display according to claim 11, further comprising:
a hole injection layer and a hole transporting layer formed between the anode and the organic lighting layer; and
an electron transporting layer and an electron injection layer formed between the organic lighting layer and the cathode.
